(19) United States
(12) Patent Application Publication
(10) Pub. No.: US 2016/0284754 A1
(43) Pub. Date: Sep. 29, 2016

(54) SEMICONDUCTOR DEVICE, SOLID-STATE IMAGING DEVICE, AND IMAGING APPARATUS

(71) Applicant: OLYMPUS CORPORATION, Tokyo (JP)

(72) Inventor: Naohiro Takazawa, Tokyo (JP)

(73) Assignee: OLYMPUS CORPORATION, Tokyo (JP)

(21) Appl. No.: 15/172,865

(22) Filed: Jun. 3, 2016

Related U.S. Application Data
(63) Continuation of application No. PCT/JP2015/050617, filed on Jan. 13, 2015.

(30) Foreign Application Priority Data
Jan. 16, 2014 (JP) 2014-005596

(51) Int. Cl. H01L 27/146; H04N 5/378

(52) U.S. Cl. CPC H01L 27/14634; H01L 27/14636; H01L 27/14618; H04N 5/378

(57) ABSTRACT

A semiconductor device includes a plurality of substrates including a semiconductor layer and a wiring layer, wherein each of the plurality of substrates is separated from and overlap other substrate of the plurality of substrates in a direction crossing a main surface, and the wiring layer of an edge substrate is arranged between the semiconductor layer of the edge substrate and the substrate adjacent to the edge substrate, a connection portion that electrically connects two adjacent substrates among the plurality of substrates, a resin layer that is arranged between the two adjacent substrates among the plurality of substrates, and a first opening portion that is formed in the semiconductor layer of the edge substrate, the shape of the first opening portion viewed in the direction squarely facing the main surface of the edge substrate being a polygon having five or more sides or a circle.

This application is a continuation application based on a PCT International Application No. PCT/JP2015/050617, filed on Jan. 13, 2015, whose priority is claimed on Japanese Patent Application No 2013-005596, filed on Jan. 13, 2014, the contents of the PCT International Application and the Japanese Patent Application are incorporated herein by reference.

### BACKGROUND OF THE INVENTION

1. Field of the Invention

The present invention relates to a semiconductor device having a plurality of overlapping (laminated) substrates, a solid-state imaging, device, and an imaging device.

2. Description of Related Art

A device having a structure in which a plurality of substrates including a semiconductor layer (including a case in which the semiconductor layer is a support substrate) and a wiring layer overlap (laminated) is known. In a solid-state imaging device described in Japanese Unexamined Patent Application, First Publication No. 2009-277732, an opening portion is formed in a semiconductor layer of an uppermost arranged substrate, and a wiring layer is exposed. A portion in which the opening portion is formed functions as a pad for electrical connection to the outside. A general method of ensuring the electrical connection to the outside includes wire bonding. In wire bonding, a metal wire is connected to the wiring layer exposed by the formation of the opening portion.

In the device in which the opening portion is formed as described above, a shape of the opening portion is generally square. Further, in the device having a structure in winch the plurality of substrates overlap, a resin is generally injected between two adjacent substrates so as to increase bonding strength of the substrates.

### SUMMARY OF THE INVENTION

According to a first aspect of the present invention, a semiconductor device includes a plurality of substrates, wherein each of the plurality of substrates includes a semiconductor layer and a wiring layer in which a wiring used for transferring a signal is formed and the wiring layer is provided to overlap the semiconductor layer, wherein each of the plurality of substrates is separated from and overlap other substrate of the plurality of substrates in a direction crossing a main surface, and the wiring layer of an edge substrate is arranged between the semiconductor layer of the edge substrate and the substrate adjacent to the edge substrate, the edge substrate being a substrate located at any one of both ends of the plurality of substrates; a connection portion that electrically connects two adjacent substrates among the plurality of substrates; a resin layer that is arranged between the two adjacent substrates among the plurality of substrates, and is provided to cover at least a portion of a surface of the connection portion; and a first opening portion that is formed in the semiconductor layer of the edge substrate and exposes the wiring layer of the edge substrate, the shape of the first opening portion viewed in the direction squarely facing the main surface of the edge substrate being a. polygon having five or more sides or a circle.

According to a second aspect of the present invention, in the semiconductor device according to the first aspect, a distance from a center of the first opening portion to each of a plurality of corner portions of the first opening portion may be the same when viewed in the direction squarely facing the main surface of the edge substrate.

According to a third aspect of the present invention, in the semiconductor device according to the first aspect, a shape of the first opening portion viewed in the direction squarely facing the main surface of the edge substrate may be a regular polygon having five or more sides.

According to a fourth aspect of the present invention, the semiconductor device according to the first aspect may include a second opening portion that is formed in the wiring layer of the edge substrate to at least partially overlap the first opening portion and exposes the wiring, a shape of the second opening portion viewed in the direction squarely facing the main surface of the edge substrate a polygon having five or more sides or a circle.

According to a fifth aspect of the present invention, in the semiconductor device according to the first aspect, all of interior angles of the polygon are 90 degrees or more.

According to a sixth aspect of the present invention, a solid-state imaging device includes the semiconductor device according to the first aspect, a photoelectric conversion unit that converts light into a signal is formed in the semiconductor layer of the edge substrate, and a signal processing unit that processes as signal generated by the photoelectric conversion unit is formed in the semiconductor layer and the wiring layer of the substrate different from the edge substrate.

According to a seventh aspect of the present invention, a solid-state imaging device includes the semiconductor device according to the first aspect, a photoelectric conversion unit that converts light into a signal is formed in the semiconductor layer of the substrate different from the edge substrate, and a signal processing unit that processes a signal generated by the photoelectric conversion unit is formed in the semiconductor layer and the wiring layer of the edge substrate.

According to an eighth aspect of the present invention, an imaging apparatus includes the solid-state imaging device according to the sixth aspect.

According to a ninth aspect of the present invention, an imaging apparatus includes the solid-state imaging device according to the seventh aspect.

### BRIEF DESCRIPTION OF THE DRAWINGS

FIG. 1 is a cross-sectional view showing an example of a configuration of a solid-state imaging device according to a first embodiment of the present invention.

FIG. 2 is a plan view showing a shape of an opening portion of the solid-state imaging device according to the first embodiment of the present invention.

FIG. 3 is a plan view showing a shape of the opening portion of the solid-state imaging device according to the first embodiment of the present invention.

FIG. 4 is a plan vim showing a shape of the opening portion of the solid-state imaging device according to the first embodiment of the present invention.

FIG. 5 is a plan view showing a shape of the opening portion of the solid-state imaging device according to the first embodiment of the present invention.

FIG. 6 is a plan view showing a shape of the opening portion of the solid-state imaging device according to the first embodiment of the present invention.

FIG. 7 is a block diagram showing an example of an entire configuration of the solid-state imaging device according to the first embodiment of the present invention.

FIG. 8 is a cross-sectional view showing an example of a configuration of a solid-state imaging device according to a second embodiment of the present invention.

FIG. 9 is a block diagram showing an example of a configuration of an imaging apparatus according to a third embodiment of the present invention.

### DETAILED DESCRIPTION OF THE INVENTION

Hereinafter, embodiments of the present invention will be described with reference to the accompanying drawings.

### FIRST EMBODIMENT

First, a first embodiment of the present invention will be described. In this embodiment, an example in which the present invention is applied to a solid-state imaging device which is an example of a semiconductor device will be described.

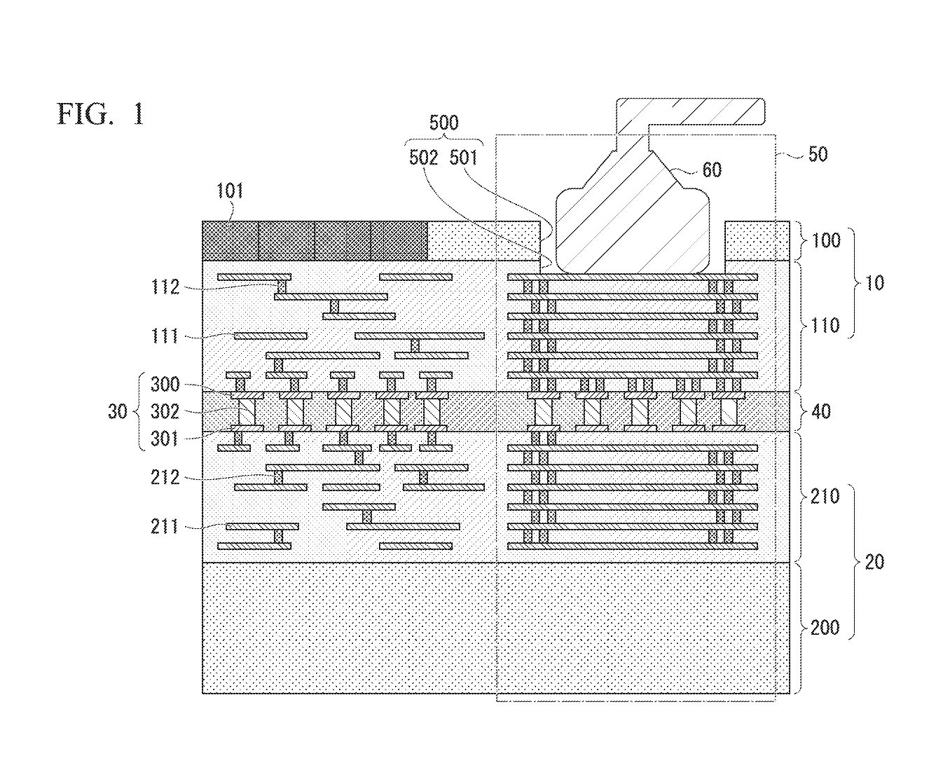

FIG. 1 shows an example of a configuration of the solid-state imaging device according to this embodiment. In FIG. 1, a cross section of the solid-state imaging device is shown. The solid-state imaging device shown in FIG. 1 includes a plurality of overlapping (laminated) substrates (a first substrate 10 and a second substrate 20), a connection portion 30, and a resin layer 40.

The dimensions of portions constituting the solid-state imaging device shown in FIG. 1 do not match the dimensions shown in FIG. 1 The dimensions of the portions constituting the solid-state imaging device shown in FIG. 1 may be arbitrary. In all of the following drawings, the ratio of the dimension of each component appropriately varies so that the drawings are easily viewed.

The first substrate 10 and the second substrate 20 overlap at a distance in a direction crossing a main surface of each substrate (a widest face among a plurality of faces constituting surfaces of the substrate) (for example, a direction substantially perpendicular to the main surface).

The first substrate 10 includes a semiconductor layer 100 and a wiring layer 110. The semiconductor layer 100 and the wiring layer 110 overlap in a direction crossing a main surface of the first substrate 10 (for example, a direction substantially perpendicular to the main surface). Further, the semiconductor layer 100 and the wiring layer 110 are in contact with each other.

The semiconductor layer 100 includes a photoelectric conversion unit 101 that converts incident light into a signal. The semiconductor layer 100 is formed of a material including a semiconductor such as silicon (Si). The photoelectric conversion unit 101 is formed of, for example, a semiconductor material having an impurity concentration different from that of the semiconductor material constituting the semiconductor layer 100. The semiconductor layer 100 includes a first face that is in contact with the wiring layer 110, and a second face that is opposite to the first face and exposed to the outside. Light incident on the second face of the semiconductor layer 100 proceeds within the semiconductor layer 100 and is incident on the photoelectric conversion unit 101.

The solid-state imaging device includes a plurality of photoelectric conversion units 101. In FIG. 1, four photoelectric conversion units 101 are shown. In FIG. 1, the reference sign of one photoelectric conversion unit 101 is shown as a representative reference sign. When the first substrate 10 is viewed in a direction squarely facing the main surface of the first substrate 10, that is, when the first substrate 10 is viewed in a plan view, the plurality of photoelectric conversion units 101 are arranged in a matrix form.

The wiring layer 110 includes wirings 111 and vias 112. The wiring 111 transfers a signal generated by the photoelectric conversion unit 101 or other signals. The vias 112 connect the wirings 111 of different layers. There are a plurality of wirings 111 in FIG. 1, but a reference sign of one wiring 111 is shown as a representative reference sign. Further, there are a plurality of vias 112 in FIG. 1, but a reference sign of one via 112 is shown as a representative reference sign. The wiring 111 is formed of a conductive material (for example, a metal such as aluminum (Al) or copper (Cu)). The wiring layer 110 includes a first face that is in contact with the resin layer 40, and a second face that is opposite to the first face and in contact with the semiconductor layer 100.

The wiring 111 is a thin film in which a wiring pattern is formed. Only one layer of wiring 111 may be formed or a plurality of layers of wirings 111 may be formed. In the example shown in FIG. 1, six layers of wirings 111 are trained. The wirings 111 of the different layers are connected using the vias 112. The via 112 is formed of a conductive material. In the wiring layer 110 a portion other than the wirings 111 and the vias 112 is formed of, for example, an interlayer insulating film such as silicon dioxide (SiO₂).

The second substrate 20 includes a semiconductor layer 200 and a wiring layer 210. The semiconductor layer 200 and the wiring layer 210 overlap in a direction crossing a main surface of the second substrate 20 (for example, a direction substantially perpendicular to the main surface). Further, the semiconductor layer 200 and the wiring layer 210 are in contact with each other.

The semiconductor layer 200 functions as a support substrate. The semiconductor layer 200 is formed of a material including a semiconductor such as silicon (Si). The semiconductor layer 200 includes a first face that is in contact with the wiring layer 210, and a second face that is opposite to the first face and exposed to the outside.

The wiring layer 210 includes wirings 211 and vias 212. The wiring 211 transfers a signal generated by the photoelectric conversion unit 101 of the first substrate 10 or other signals. The vias 212 connect the wirings 211 of different layers. There are a plurality of wirings 211 in FIG. 1, but a reference sign of one wiring 211 is shown as a representative reference sign. Further, there are a plurality of vias 212 in FIG. 1, but a reference sign of one via 212 is shown as a representative reference sign. The wiring 211 is formed of a conductive material (for example, a metal such as aluminum (Al) or copper (Cu)). The wiring layer 210 includes a first face that is in contact with the resin layer 40, and a second face that is opposite to the first face and is in contact with the semiconductor layer 200.

The wiring 211 is a thin film in which a wiring pattern is formed. Only one layer of wiring 211 may be formed or a plurality of layers of wirings 211 may be formed. In the example shown in FIG. 1, six layers of wirings 211 are formed. The wirings 211 of the different layers are connected using the vias 212. The via 212 is formed of a conductive material. In the wiring layer 210, a portion other than the wirings 211 and the vias 212 is formed of, for example, an interlayer insulating film such as silicon dioxide (SiO₂).

The connection portion 30 is arranged between two adjacent substrates among a plurality of substrates included in the solid-state imaging device, and electrically connects the two substrates. In FIG. 1, the connection portion 30 is arranged between the first substrate 10 and the second substrate 20 and electrically connects the first substrate 10 and the second substrate 20. In FIG. 1, there are a plurality of connection portions 30, but the reference sign of one connection portion 30 is shown as a representative reference sir. The connection portion 30 is formed of a conductive material (for example, a metal such as gold (Au) or copper (Cu)).

The connection portion 30 includes connection electrodes 300 and 301, and a bump 302. The connection electrode 300 is connected to the via 112 of the wiring layer 110. The connection electrode 301 is connected to the via 212 of the wiring layer 210. At least a portion of the surface of the connection portion 30 is covered with the resin layer 40. At least the portion of the surface of the connection portion 30 described above is a surface of the connection portion 30 other than a surface that is in contact with the wiring layer 110 and a surface that is in contact with the wiring layer 210.

The resin layer 40 is arranged between the two adjacent substrates among the plurality of substrates included in the solid-state imaging device, and connects the two substrates. In FIG. 1, the resin layer 40 is arranged between the first substrate 10 and the second substrate 20, and connects the first substrate 10 and the second substrate 20. The resin layer 40 is formed of for example, an epoxy resin. Bonding strength between the substrates further increases due to the resin layer 40.

The first substrate 10 and the second substrate 20 are connected via the resin layer 40 in a state in which the wiring layer 110 of the first substrate 10 faces the wiring layer 210 of the second substrate 20. The resin layer 40 is in contact with the first face of the wiring layer 110 and the first face of the wiring layer 210. Further, the resin layer 40 covers at least a portion of the surface of the connection portion 30.

In the semiconductor layer 100, an opening portion 500 is formed in a pad region 50 for electrical connection to the outside. By the opening portion 500 being formed, the wiring layer 110 is exposed in the pad region 50. In FIG. 1, an uppermost wiring 111 of the wiring layer 110 is exposed.

The opening portion 500 includes side walls of the semiconductor layer 100, and side walls of the wiring layer 110. The side walls of the semiconductor layer 100 are exposed by formation of a hole passing through the semiconductor layer 100. The side walls of the wiring layer 110 are exposed by a groove being formed in the wiring layer 110. That is, the opening portion 500 includes a first opening portion 501 and a second opening portion 502. The first opening portion 501 is formed in the semiconductor layer 100 and is formed to expose the wiring layer 110. The second opening portion 502 is formed in the wiring layer 110 to at least partially overlap the first opening portion 501 and is formed to expose the wiring 111. The exposed wiring 111 functions as a pad which is an electrode for electrical connection to the outside. A wire 60 is connected to the wiring 111 through wire bonding.

When the wiring layer 110 and the wire 60 can he connected in as position of the second face of the wiring layer 110 due to the structure in which, for example, the wiring 111 is exposed to the second face of the wiring layer 110, the second opening portion 502 may not be formed. Accordingly, in this embodiment, the second opening portion 502 is not an essential structure.

In this embodiment, the first substrate 10 and the second substrate 20 are electrically connected by the connection portion 30 including the bumps 302, but a method of mounting the connection portion that electrically connects the two adjacent substrates is not limited to the method described in this embodiment. For example, the two adjacent substrates may be electrically connected by a through-silicon via (TSV). Further, the two adjacent substrates may be electrically connected by directly bonding connection electrodes formed in the two respective adjacent substrates without forming the bumps.

Although the solid-state imaging device shown in FIG. 1 includes the two substrates, the solid-state imaging device may include three or mote substrates. Each of the plurality of substrates included in the solid-state imaging device may include a semiconductor layer and as wiring layer.

The substrate located at any one of both ends of the plurality of substrates included in the solid-state imaging device is an edge substrate. In this embodiment, the wiring layer of the edge substrate may be arranged between the semiconductor layer of the edge substrate and the substrate adjacent to the edge substrate. The edge substrate is a substrate arranged on the outermost side among the plurality of substrates, which is a substrate having a main surface that is not in contact with the other substrates among the plurality of substrates. In other words, the edge substrate is a substrate arranged on the uppermost side or the lowermost side among the plurality of substrates when the plural of substrates are arranged so that the main surface of at least one of the plurality of substrates is substantially parallel to a horizontal plane. If the solid-state imaging device includes two substrates, any one of the two substrates is the edge substrate. In the solid-state imaging device shown in FIG. 1, the first substrate 10 is the edge substrate.

The semiconductor layer included in the edge substrate may be arranged on the outer side relative to the wiring layer included in the edge substrate. Further, a photoelectric conversion unit that converts light into a signal may be formed in the semiconductor layer of the edge substrate.

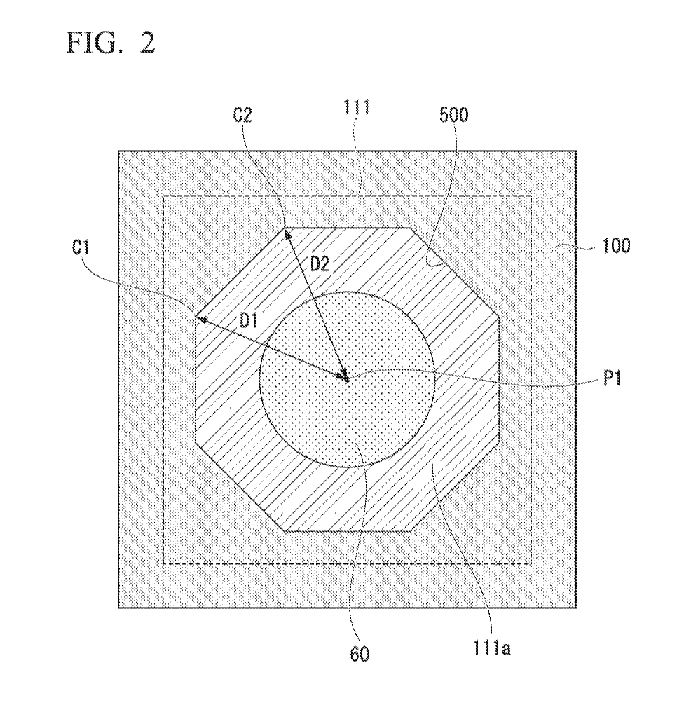

FIG. 2 shows a shape of the opening portion 500, that is, a planar shape of the opening portion 500 when viewed in a direction squarely facing the main surface of the first substrate 10 (a direction substantially perpendicular to the main surface of the first substrate 10). As shown in FIG. 2. the opening portion 500 is formed in the semiconductor layer 100, and a surface 111a of the wiring 111 is exposed. The wire 60 is connected to a center of the surface 111a of the exposed wiring 111.

As shown in FIG. 2, the shape of the opening portion 500 is a regular octagon. The opening portion 500 has eight corner portions located at vertices of the regular octagon, and has eight straight portions which are sides of the regular octagon. When the number of corner portions is greater than that in the related art, it is possible to disperse as stress at the corner portion at which the stress tends to concentrate at the time of wire bonding. This configuration can prevent cracks from occurring.

There is a center P1 of the opening portion 500 at an intersection of perpendicular bisectors of the eight straight portions. A distance D1 from the center P1 to the corner portion C1 and a distance D2 from the center P1 to the corner portion C2 are the same. A distance from the center P1 to each of the other six corner portions is also the same as the distances D1 and D2. Since the distances from the center P1 to the corner portions are the same, the flexure of the semiconductor layer 100 at the time of wire bonding can be uniform, and the stress at the corner portion can be uniform. Accordingly, it is possible to prevent cracks from occurring. The center P1 may be a center of gravity of the opening portion 500.

In FIG. 2, a shape of the first opening portion 501 formed in the semiconductor layer 100 and constituting the opening portion 500 and a shape of the second opening portion 502 formed in the wiring layer 110 are the same. Only the shape of the first opening portion 501 may be a regular octagon. By setting the shape of the first opening portion 501 to the regular octagon, it is possible to prevent cracks from occurring in the semiconductor layer 100 due to a stress generated in the semiconductor layer 100 at the time of wire bonding. By setting the shape of the second opening portion 502 to the regular octagon, it is possible to prevent cracks from occurring in the wiring layer 110 due to a stress generated in the wiring layer 110 at the time of wire bonding.

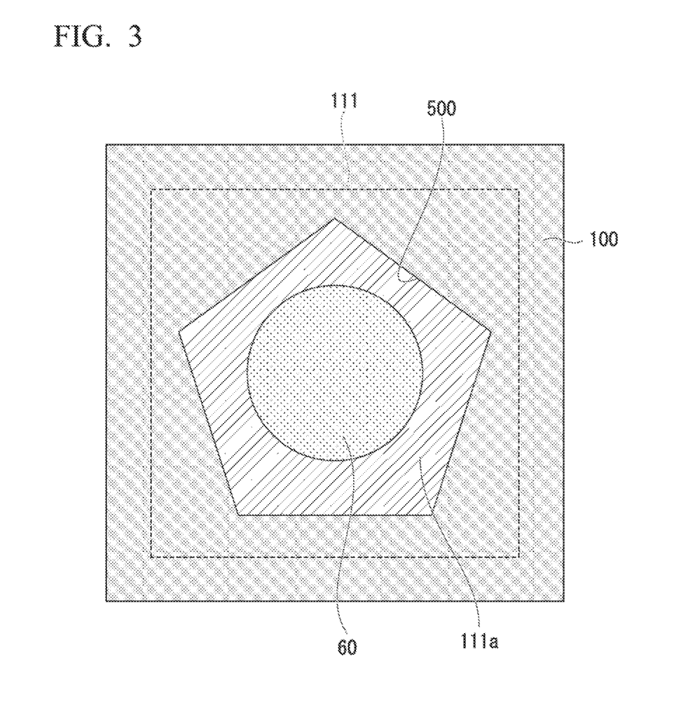

The shape of the opening portion 500 may be a polygon other than the regular octagon. FIGS. 3, 4, and 5 show other shapes of the opening portion 500 when viewed in a direction squarely facing the main surface of the first substrate 10. In FIGS. 3, 4, and 5, the opening portion 500 is formed in the semiconductor layer 100, and the surface 111a of the wiring 111 is exposed. Further, the wire 60 is connected to a center of the exposed surface 111a of the wiring 111.

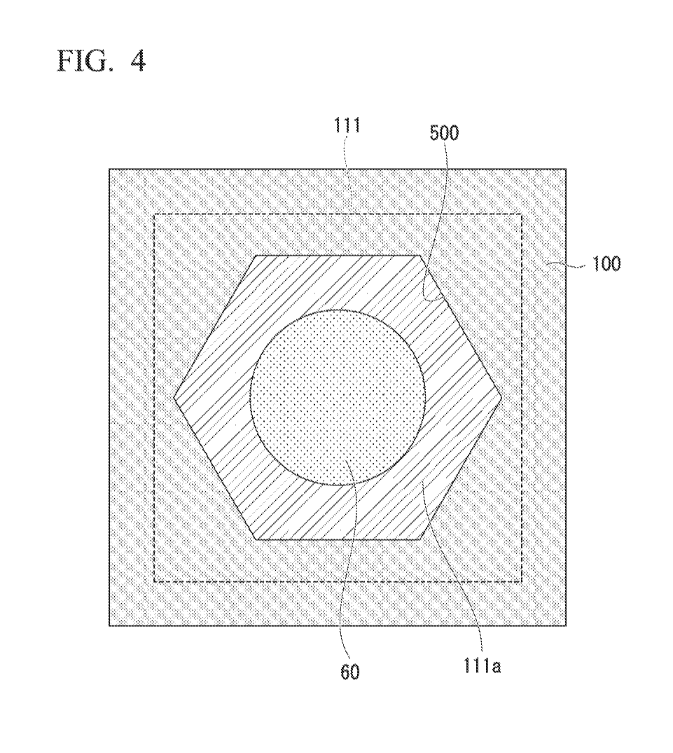

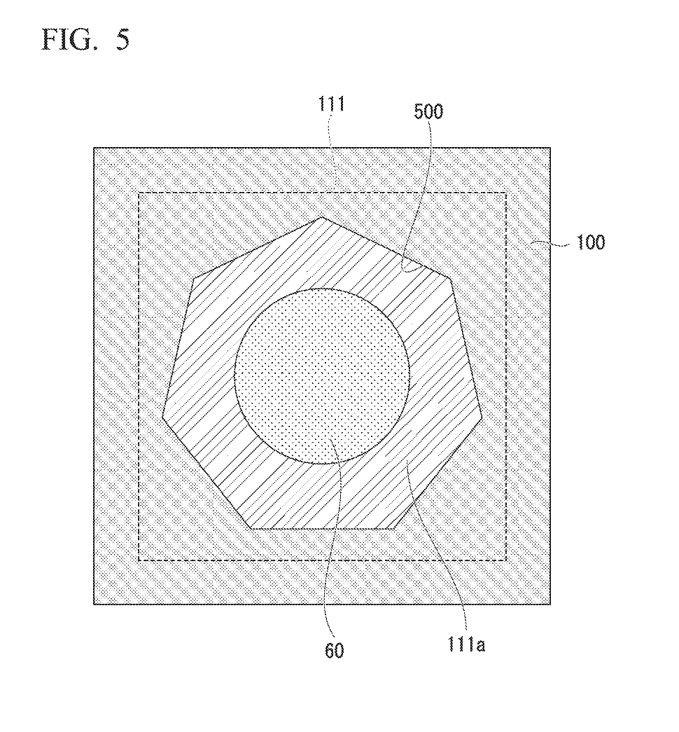

In FIG. 3, the shape of the opening portion 500 is a regular pentagon. In FIG. 4, the shape of the opening portion 500 is a regular hexagon. In FIG. 5, the shape of the opening portion 500 is a regular heptagon. Even when the shape of the opening portion 500 is any one of the regular pentagon, the regular hexagon, and the regular heptagon, the number of corner portions is more than the number of corner portions of the related art. Accordingly, it is possible to prevent cracks from occurring. Further, even when the shape of the opening portion 500 is any one of the regular pentagon, the regular hexagon, and the regular heptagon, a distance from the center to the corner portion is the same. Accordingly, it is possible to prevent cracks from occurring.

The shape of the opening portion 500 may be a polygon having five or more sides. A corner of the polygon constituting the opening portion 500 may be rounded. The polygon constituting the opening portion 500 may have five or more straight portions different directions. The polygons constituting the opening portion 500 may not be a regular polygon. It is preferable for a distance from the center of the opening portion 500 to each of a plurality of corner portions of the opening portion 500 to be the same. It is preferable for all of interior angles of the polygon constituting the opening portion 500 to be 90 degrees or more.

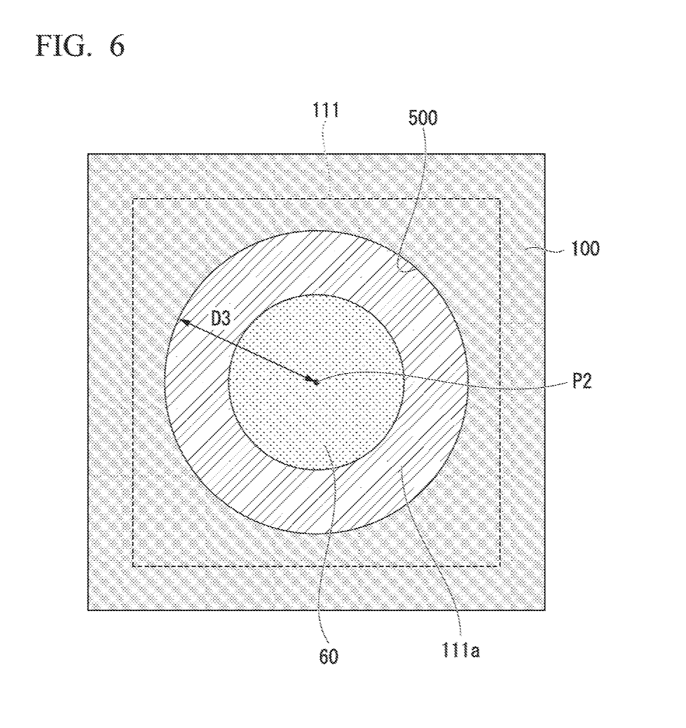

The shape of the opening portion 500 may be a circle. FIG. 6 shows the shape of the opening portion 500 when viewed in a direction squarely facing the main surface of the first substrate 10. In FIG. 6, the shape of the opening portion 500 is a circle. A distance D3 from the center P2 of the opening portion 500 to the periphery of the opening portion 500 is uniform. Since the distance from the center P2 to the periphery of the opening portion 500 is uniform, the flexure of the semiconductor layer 100 at the time of wire bonding becomes uniform, and a stress generated on the periphery of the opening portion 500 can be uniformly controlled. Accordingly, it is possible to prevent cracks from occurring.

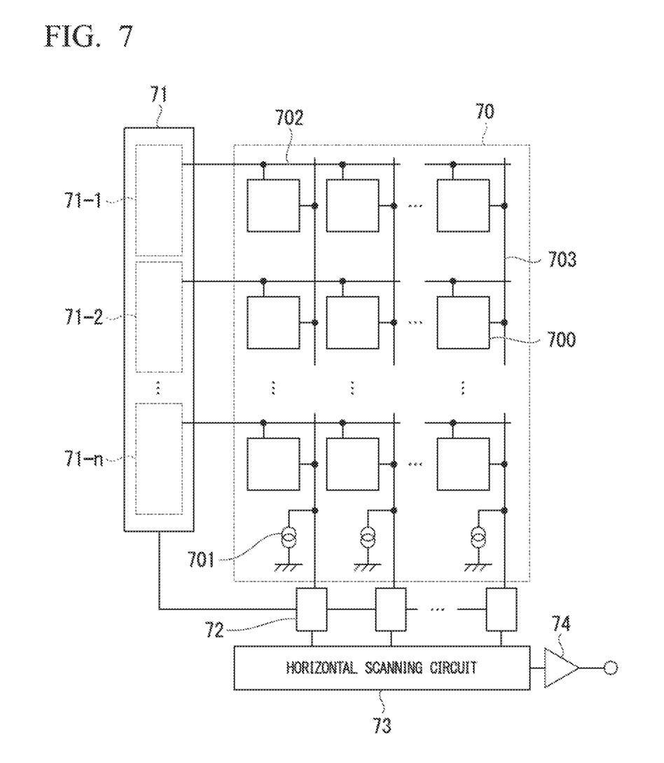

FIG. 7 shows an example of an configuration of a solid-state imaging device. The solid-state imaging device shown in FIG. 7 includes a pixel unit 70 (pixel array), a. vertical scanning circuit 71, a column processing circuit 72, a horizontal scanning circuit 73, and an output amplifier 74. An arrangement position of each circuit element shown in FIG. 7 does not necessarily match an actual arrangement position.

The pixel unit 70 includes pixels 700 arranged in a two-dimensional matrix form, and a current source 701 provided in each column. The pixel 700 includes the photoelectric conversion unit 101 shown in FIG. 1. The vertical scanning circuit 71 performs driving, control of the pixel unit 70 in units of rows. To perform this driving control, the vertical scanning circuit 71 includes unit circuits 71-1, 71-2, . . . , and 71-n (n is the number of rows) in the same number as the number of rows.

Each unit circuit 71-i (i=1, 2, . . . , n) outputs a control signal for controlling the pixels 700 of one row to a signal line 702 provided in each row. The signal line 702 is connected to the pixels 700 and supplies the control signal output from the unit circuit 71-i to the pixels 700. In FIG. 7, although the signal line 702 corresponding to each row is represented as one line, each signal line 702 includes a plurality of signal lines. A signal of the pixel 700 of the row selected by the control signal is output to a vertical signal line 703 provided in each column.

The current source 701 is connected to the vertical signal line 703, and constitutes an amplifying transistor and a source follower circuit in the pixel 700. The column processing circuit 72 performs signal processing such as noise suppression on a pixel signal output to the vertical signal line 703. The horizontal scanning circuit 73 outputs the pixel signals of the pixels 700 of one row output to the vertical signal line 703 and processed by the column processing circuit 72 to the output amplifier 74 in chronological order. The output amplifier 74 amplifies the pixel signal output from the horizontal scanning circuit 73, and outputs the amplified pixel signal to the outside of the solid-state imaging device as an image signal.

The pixel unit 70 is arranged on the first substrate 10. The vertical scanning circuit 71, the horizontal scanning circuit 73, and the output amplifier 74 may be arranged on either the first substrate 10 or the second substrate 20. The column processing circuit 72 is a signal processing unit that processes a signal generated by the photoelectric conversion unit 101. The column processing circuit 72 is formed in the semiconductor layer 200 and the wiring layer 210 of the second substrate 20 different from the first substrate 10 in which the photoelectric conversion unit 101 is formed.

Although the example in which the present invention is applied to the solid-state imaging device including the photoelectric conversion unit has been described in this embodiment, the present invention is applicable to a semiconductor device including a plurality of substrates having a semiconductor layer and a wiring layer,

According to this embodiment, the semiconductor device is configured to include the plurality of substrates (the first substrate 10 and the second substrate 20) including the semiconductor layers 100 and 200 and the wiring layers 110 and 210 in which the wirings 111 and 211 for transferring signals are formed and that overlap the semiconductor layers 100 and 200, the respective substrates overlapping at a distance in a direction crossing the main surface, and the wiring layer 110 of the edge substrate (the first substrate 10) that is a substrate located at any one of both ends of the plurality of substrates being arranged between the semiconductor layer 100 of the edge substrate and the substrate (the second substrate 20) adjacent to the edge substrate: the connection portion 30 that electrically connects two adjacent substrates among the plurality of substrates; the resin layer 40 that is arranged between the two adjacent substrates among the plurality of substrates, and covers at least a portion of the surface of the connection portion 30; and the first opening portion 501 that is formed in the semiconductor layer 100 of the edge substrate and exposes the wiring layer 110 of the edge substrate, the shape of the first opening portion viewed in the direction squarely facing the main surface of the edge substrate being a polygon having five or more sides or a circle.

In this embodiment, since the shape of the first opening portion 501 viewed in the direction squarely facing the main surface of the first substrate 10 is a polygon having five or more sides or a circle, it is possible to prevent cracks from occurring.

Since a distance from a center of the first opening portion 501 to each of the plurality of corner portions of the first opening portion 501 is the same When viewed in the direction squarely facing the main surface of the first substrate 10, the flexure of the semiconductor layer 100 at the time of wire bonding is uniform and a stress at the coiner portion is uniform. Therefore, it is possible to further prevent cracks from occurring.

The shape of the first opening portion 501 viewed in the direction squarely facing the main surface of the first substrate 10 is a regular polygon having five or more sides. Therefore, the flexure of the semiconductor layer 100 at the time of wire bonding is uniform, and the stress at the corner portion is uniform, unlike a case in which the shape of the first opening portion 501 is a polygon other than the regular polygon. Therefore, it is possible to further prevent cracks from occurring.

Since the second opening portion 502 formed to at least partially overlap the first opening portion 501 and exposing the wiring 111, in which the shape of the second opening portion 502 viewed in the direction squarely facing the main surface of the first substrate 10 is a polygon having five or more sides or a circle, is formed in the wiring layer 110 of the first substrate 10, it is possible to prevent cracks from occurring in the wiling layer 110.

Since all interior angles of the polygon constituting the first opening portion 501 or the second opening portion 502 are 90 degrees or more, it is possible to further prevent cracks from occurring.

### SECOND EMBODIMENT

Next, a second embodiment of the present invention will be described. In this embodiment, an example in which the present invention is applied to a solid-state imaging device which is an example of a semiconductor device will be described.

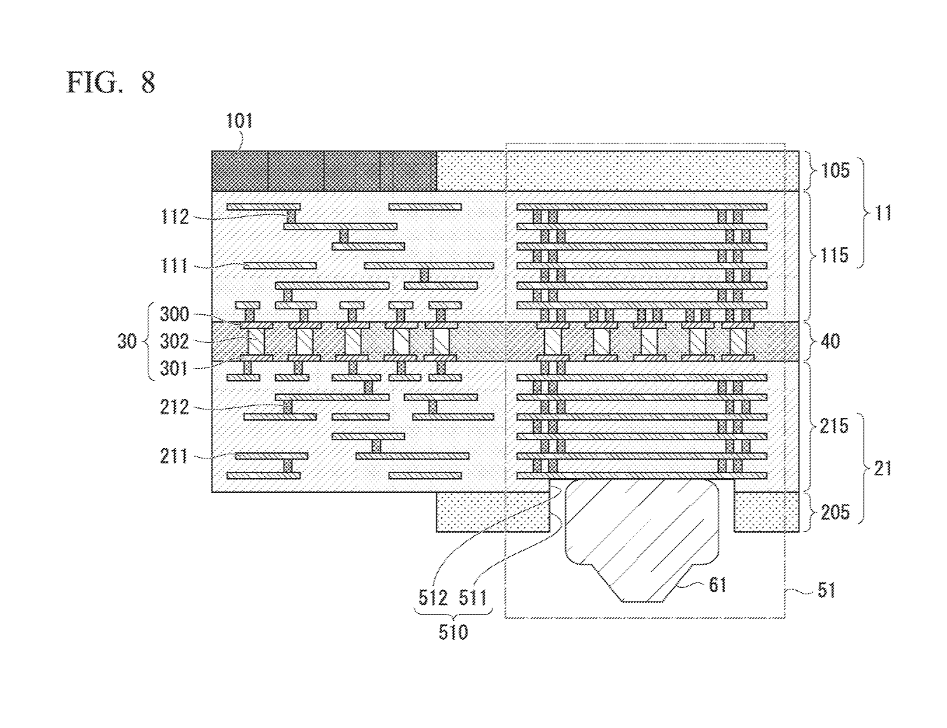

FIG. 8 shows an example of a configuration of a solid-state imaging device according to this embodiment. A cross-section of the solid-state imaging device is shown in FIG. 8. The solid-state imaging device shown in FIG. 8 includes a plurality of overlapping (laminated) substrates (a first substrate 11 and a second substrate 21), a connection portion 30, and a resin layer 40. Hereinafter, description of the above-described configuration will be omitted.

The dimensions of portions constituting the solid-state imaging device shown in FIG. 8 do not match the dimensions shown in FIG. 8 The dimensions of the portions constituting the solid-state imaging device shown in FIG. 8 may be arbitrary.

The first substrate 11 and the second substrate 21 overlap at a distance in a direction crossing a main surface of each substrate (for example, a direction substantially perpendicular to the main surface).

The first substrate 11 includes a semiconductor layer 105 and a wiring layer 115. The semiconductor layer 105 and the wiring layer 115 overlap in a direction crossing a main surface of the first substrate 11 (for example, a direction substantially perpendicular to the main surface). The semiconductor layer 105 and the wiring layer 115 are in contact with each other.

The semiconductor layer 105 includes a photoelectric conversion unit 101. In this embodiment, the opening portion 500 shown in FIG. 1 is not formed. The semiconductor layer 105 is the same as the semiconductor layer 100 shown in FIG. 1 except that there is no opening portion 500.

The wiring layer 115 includes wirings 111 and vias 112. There are a plurality of wirings 111 in FIG. 8, but a reference sign of one wiring 111 is shown as a representative reference sign. Further, there are a plurality of vias 112 in FIG. 8, but a reference sign of one via 112 is shown as a representative reference sign. The wiring layer 115 is the same as the wiring layer 110 shown in FIG. 1 except that there is no opening portion 500.

The second substrate 21 includes a semiconductor layer 205 and a wiring layer 215. The semiconductor layer 205 and the wiring layer 215 overlap in a direction crossing a main surface of the second substrate 21 (for example, a direction substantially perpendicular to the main surface). Further, the semiconductor layer 205 and the wiring layer 215 are in contact with each other.

The semiconductor layer 205 functions as a support substrate. The semiconductor layer 205 is formed to be thinner than the semiconductor layer 200 shown in FIG. 1. In this embodiment an opening portion 510 to be described below is formed. The semiconductor layer 205 is the same as the semiconductor layer 100 shown in FIG. 1 except that there is the opening portion 510.

The wiring layer 215 includes wirings 211 and vias 212. There are a plurality of wirings 211 in FIG. 8, but a reference sign of one wiring 211 is shown as a representative reference sign. Further, there are a plurality of vias 212 in FIG. 8, but a reference sign of one via 212 is shown as a representative reference sign. The wiring layer 215 is the same as the wiring layer 210 shown in FIG. 1 except that there is the opening portion 510.

In the semiconductor layer 205, the opening portion 510 is formed in a pad region 51 for electrical connection to the outside. By the opening portion 510 being formed, the wiring layer 215 is exposed in the pad region 51. In FIG. 8, a lowermost wiring 211 of the wiring layer 215 is exposed.

The opening portion 510 includes side walls of the semiconductor layer 205, and side walls of the wiring layer 215. The side walls of the semiconductor layer 20 are exposed by formation of a hole passing through the semiconductor layer 205. The side walls of the wiring layer 215 are exposed by a groove being formed in the wiring layer 215. That is, the opening portion 510 includes a first opening portion 511 and a second opening portion 512. The first opening portion 511 is formed in the semiconductor layer 205 and is formed to expose the wiring layer 215. The second opening portion 512 is formed in the wiring layer 215 to at least partially overlap the first opening portion 511 and is formed to expose the wiring 211. The exposed wiring 211 functions as a pad, which is an electrode for electrical connection to the outside. A stud bump 61 is connected to the wiring 211 using stud bump bonding. The stud bump 61 is electrically connected to a circuit board using a method such as flip chip bonding. Accordingly, it is possible to mount the solid-state imaging device on the circuit board.

When the wiring layer 215 and the stud bump 61 can be connected in a position of the second face of the wiring layer 215 due to the structure in which, for example, the wiring 211 is exposed to the second face of the wiring layer 215, the second opening portion 512 may not be formed. Accordingly, in this embodiment, the second opening portion 512 is not an essential structure.

In this embodiment, the first substrate 11 and the second substrate 21 are electrically connected by the connection portion 30 including the bumps 302, but a method of mounting the connection portion that electrically connects the two adjacent substrates is not limited to the method described in this embodiment. For example, the two adjacent substrates may be electrically connected by a through-silicon via. Further, the two adjacent substrates may be electrically connected by directly bonding connection electrodes formed in the two respective adjacent substrates without forming the bumps.

Although the solid-state imaging device shown in FIG. 8 includes the two substrates, the solid-state imaging device may include three or more substrates. Each of the plurality of substrates included in the solid-state imaging device may include a semiconductor layer and a wiring layer.

The substrate located at any one of both ends of the plurality of substrates included in the solid-state imaging device is an edge substrate. In this embodiment, the wiring layer of the edge substrate may be arranged between the semiconductor layer of the edge substrate and the substrate adjacent to the edge substrate. The edge substrate is a substrate arranged on the outermost side among the plurality of substrates, which is a substrate having a main surface that is not in contact with the other substrates among the plurality of substrates. In other words, the edge substrate is a substrate arranged on the uppermost side or the lowermost side among the plurality of substrates when the plurality of substrates are arranged so that the main surface of at least one of the plurality of substrates is substantially parallel to a horizontal plane. If the solid-state imaging device includes two substrates, any one of the two substrates is the edge substrate. In the solid-state imaging device shown in FIG. 8, the second substrate 21 is the edge substrate.

The semiconductor layer included in the edge substrate may be arranged on the outer side relative to the wiring layer included in the edge substrate. Further, a photoelectric conversion unit that converts light into a signal may be formed in the semiconductor layer of the substrate different from the edge substrate.

A shape of the opening portion 510 viewed in a direction squarely facing the main surface of the second substrate 21 (a direction substantially perpendicular to the main surface of the second substrate 21) is the same as the shape of the opening portion 500 shown in FIG. 1. That is, the shape of the opening portion 510 may be a polygon having five or more sides. A corner of the polygon constituting the opening portion 510 may be rounded. The polygon constituting the opening portion 510 may have five or more straight portions in different directions. The polygons constituting the opening portion 510 may not be a regular polygon. It is preferable for a distance from the center of the opening portion 510 to each of a plurality of corner portions of the opening portion 510 to be the same. It is preferable for all of interior angles of the polygon constituting the opening portion 510 to be 90 degrees or more. Further, the shape of the opening portion 510 may be a circle.

In FIG. 8, a shape of the first opening portion 511 formed in the semiconductor layer 205 and constituting the opening portion 510 and a shape of the second opening portion 512 formed in the wiring layer 215 are the same. By setting the shape of the first opening portion 511 to a polygon having five or more sides, it is possible to prevent cracks from occurring in the semiconductor layer 205 due to a stress generated in the semiconductor layer 205 at the time of, for example, flip chip bonding. By setting the shape of the second opening portion 512 to the polygon having five or more sides, it is possible to prevent cracks from occurring in the wiring layer 215 due to a stress generated in the wiring layer 215 at the time of, for example, flip chip bonding.

An entire configuration of the solid-state imaging device according to this embodiment is the same as that shown in FIG. 7. The pixel unit 70 shown in FIG. 7 is arranged on the first substrate 11. The vertical scanning circuit 71, the horizontal scanning circuit 73, and the output amplifier 74 shown in FIG. 7 may be arranged on either the first substrate 11 or the second substrate 21. The column processing circuit 72 is a signal processing unit that processes a signal generated by the photoelectric conversion unit 101. The column processing circuit 72 is formed in the semiconductor layer 205 or the wiring layer 215 of the second substrate 21 different from the first substrate 11 in which the photoelectric conversion unit 101 is formed.

Although the example in which the present invention is applied to the solid-state imaging device including the photoelectric conversion unit has been described in this embodiment, the present invention is applicable to a semiconductor device including a plurality of substrates having a semiconductor layer and a wiring layer.

According to this embodiment, the semiconductor device is configured to include the plurality of substrates (the first substrate 11 and the second substrate 21) including the semiconductor layers 105 and 205 and the wiring layers 115 and 215 in which the wirings 111 and 211 for transferring signals are formed and that overlap the semiconductor layers 105 and 205, the respective substrates overlapping at a distance in a direction crossing the main surface, and the wiring layer 115 of the edge substrate (the second substrate 21) that is a substrate located at any one of both ends of the plurality of substrates being arranged between the semiconductor layer 205 of the edge substrate and the substrate (the first substrate 11) adjacent to the edge substrate; the connection portion 30 that electrically connects two adjacent substrates among the plurality of substrates; the resin layer 40 that is arranged between the two adjacent substrates among the plurality of substrates, and covers at least a portion of the surface of the connection portion 30; and the first opening portion 511 that is formed on the semiconductor layer 205 of the edge substrate and exposes the wiring layer 215 of the edge substrate, the shape of the first opening portion viewed in the direction squarely facing the main surface of the edge substrate being a polygon having five or more sides or a circle.

In this embodiment, since the shape of the first opening portion 511 viewed in the direction squarely facing the main surface of the second substrate 21 is a polygon having five or more sides or a circle, it is possible to prevent cracks from occurring.

Since a distance from a center of the first opening portion 511 to each of the plurality of corner portions of the first opening portion 511 is the same when viewed in the direction squarely facing the main surface of the second substrate 21, the flexure of the semiconductor layer 205 at the tine of flip chip bonding is uniform and a stress at the corner portion is uniform. Therefore, it is possible to further prevent cracks from occurring.

The shape of the first opening portion 511 viewed in the direction squarely facing the main surface of the second substrate 21 is a regular polygon having five or more sides. Therefore, the flexure of the semiconductor layer 205 at the time of, for example, flip chip bonding is uniform, and the stress at the corner portion is uniform, unlike a case in which the shape of the first opening portion 511 is a polygon other than the regular polygon. Therefore, it is possible to further prevent cracks from occurring.

Since the second opening portion 512 formed to at least partially overlap the first opening portion 511 and exposing the wiring 211, in which the shape of the second opening portion 512 viewed in the direction squarely facing the main surface of the second substrate 21 is a polygon having five or more sides or a circle, is formed in the wiring layer 215 of the second substrate 21, it is possible to prevent cracks from occurring in the wiring layer 215.

Since all interior angles of the polygon constituting the first opening portion 511 or the second opening portion 512 are 90 degrees or more, it is possible to further prevent cracks from occurring.

### THIRD EMBODIMENT

Next, a third embodiment of the present invention will be described. In this embodiment, an example in which the present invention is applied to an imaging apparatus having a solid-state imaging device will be described.

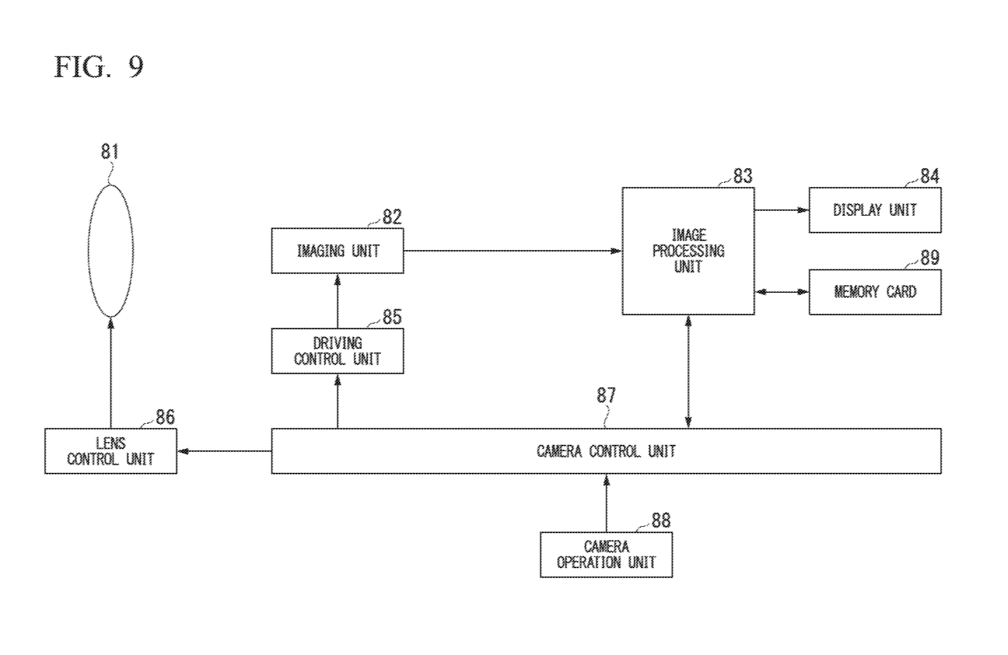

FIG. 9 shows an example of a configuration of the imaging apparatus according to this embodiment. The imaging apparatus according to this embodiment may be an electronic device having an imaging function, or may be, for example, a digital video camera or an endoscope, as well as a digital camera.

The imaging apparatus shown in FIG. 9 includes a lens 81, an imaging unit 82, an image processing unit 83, a display unit 84, a driving control unit 85, a lens control unit 86, a camera control unit 87, and a camera operation unit 88. Although a memory card 89 is also shown in FIG. 9, this memory card 89 may be detachably attached to the imaging apparatus. That is, the memory card 89 may not be a configuration specific to the imaging apparatus.

The lens 81 is an imaging lens for forming an optical image of a subject on an imaging surface of the imaging unit 82 constituting the solid-state imaging device. The imaging unit 82 converts the optical image of the subject formed by the lens 81 into a digital image signal through photoelectrical conversion. The imaging unit 82 is a solid-state imaging device according to the first embodiment or the second embodiment. The image processing unit 83 performs various types of digital image processing on the image signal output from the imaging unit 82.

The display unit 84 displays an image based on the image signal subjected to image processing for display by the image processing unit 83. The display unit 84 can display a still image and perform a moving image (live view) display to display an image in an imaging range in real time, The driving control unit 85 controls the operation of the imaging unit 82 based on an instruction from the camera control unit 87. The lens control unit 86 controls a diaphragm or a focal position of the lens 81 based on an instruction from the camera control unit 87.

The camera control unit 87 controls the entire imaging apparatus. The operation f the camera control unit 87 is defined in a program stored in a ROM built into the imaging apparatus. The camera control unit 87 reads this program and performs various controls according to content defined by the program.

The camera operation unit 88 includes various members for an operation used for a user to perform various operation inputs to the imaging apparatus, and outputs a signal based on a result of the operation input to the camera control unit 87. Specific examples of the camera operation unit 88 includes a power switch for turning on and off a power supply of the imaging apparatus, a release button for instructing still image capturing, and a still image capturing mode switch for switching a still image capturing mode between a single imaging mode and a continuous imaging mode. The memory card 89 is a recording medium for storing the image signal processed for recording by the image processing unit 83.

In this embodiment any of the solid-state imaging devices according to the first embodiment and the second embodiment is used as the imaging unit 82. Therefore, it is possible to prevent cracks from occurring in the solid-state imaging device.

While preferred embodiments of the invention have been described and shown above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A semiconductor device, comprising:
a plurality of substrates, wherein
each of the plurality of substrates includes:
a semiconductor layer, and
a wiring layer in which a wiring used for transferring a signal is formed and the wiring layer is provided to overlap the semiconductor layer, wherein
each of the plurality of substrates is separated from and overlap other substrate of the plurality of substrates in a direction crossing a main surface, and
the wiring layer of an edge substrate is arranged between the semiconductor layer of the edge substrate and the substrate adjacent to the edge substrate, the edge substrate being a substrate located at any one of both ends of the plurality of substrates:
a connection portion that electrically connects two adjacent substrates among the plurality of substrates;
a resin layer that is arranged between the two adjacent substrates among the plurality of substrates, and is provided to cover at least a portion of a surface of the connection portion; and
a first opening portion that is formed in the semiconductor layer of the edge substrate and exposes the wiring layer of the edge substrate, the shape of the first opening portion viewed in the direction squarely facing the main surface of the edge substrate being a polygon having five or more sides or a circle.

2. The semiconductor device according to claim 1,
wherein a distance from a center of the first opening portion to each of a plurality of corner portions of the first opening portion is the same when viewed in the direction squarely facing the main surface of the edge substrate.

3. The semiconductor device according to claim 1,
wherein a shape of the first opening portion viewed in the direction squarely facing the main surface of the edge substrate is a regular polygon having five or more sides.

4. The semiconductor device according to claim 1, further comprising:
a second opening portion that is formed in the wiring layer of the edge substrate to at least partially overlap the first opening portion and exposes the wiring, a shape of the second opening portion viewed in the direction squarely facing the main surface of the edge substrate is a polygon having five or more sides or a circle.

5. The semiconductor device according to claim 1,
wherein all of interior angles of the polygon are 90 degrees or more.

6. A solid-state imaging device, comprising:
the semiconductor device according to claim 1,
wherein a photoelectric conversion unit that converts light into a signal is formed in the semiconductor layer of the edge substrate, and
a signal processing unit that processes a signal generated by the photoelectric conversion unit is formed in the semiconductor layer and the wiring layer of the substrate different from the edge substrate.

7. A solid-state imaging device, comprising:
the semiconductor device according to claim 1,
wherein a photoelectric conversion unit that converts light into a signal is formed in the semiconductor layer of the substrate different from the edge substrate, and
a signal processing unit that processes a signal generated by the photoelectric conversion unit is formed in the semiconductor layer and the wiring layer of the edge substrate.
